(19) United States
(12) Patent Application Publication
(10) Pub. No.: US 2010/0141293 A1
(43) Pub. Date: Jun. 10, 2010

(54) LCD PANELS CAPABLE OF DETECTING CELL DEFECTS, LINE DEFECTS AND LAYOUT DEFECTS

(76) Inventors: Ying-Hui Chen, Taoyuan City (TW); Yi-Cheng Tsai, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/357,412

(22) Filed: Jan. 22, 2009

(30) Foreign Application Priority Data
Dec. 8, 2008 (TW) 097221944

(51) Int. Cl. G01R 31/00

(52) U.S. Cl. 324/770

(57) ABSTRACT

An LCD panel includes a plurality of signal lines, a plurality of display units, a driving circuit and a test unit. Each display unit is coupled to a corresponding signal line of the plurality of signal lines. The driving circuit is coupled to corresponding signals lines via a plurality of output ends. The test unit includes a shorting bar, a test pad, and a plurality of switches. Each switch is coupled between a corresponding signal line of the plurality of signal lines and the shorting bar.

### BACKGROUND OF THE INVENTION

1. Field of the Invention

The present invention is related to an LCD panel, and more particularly, to an LCD panel capable of detecting cell defects, line defects and layout defects using shorting bars.

2. Description of the Prior Art

Liquid crystal display (LCD) devices, characterized in low radiation, small size and low power consumption, have gradually replaced traditional cathode ray tube (CRT) devices and are widely used in electronic products, such as laptop computers, personal digital assistants (PDAs), flat panel TVs, or mobile phones. The manufactures of LCD devices mainly include array process, cell process and module process. Normally, various tests need to be performed after each process in order to eliminate defect product and reduce subsequent costs. For example, in the cell test, test signals are inputted to scan lines and data lines, while a test light is provided at the backside of the LCD panel. It can then be determined whether the LCD panel under test can function normally (such as whether light/dark spots appear or whether the reaction time meets standard). When failing to meet product specification, the LCD panel under test is scraped immediately instead of moving on to subsequent processes. Therefore, no effort needs to be spent in assembling and reworking the defect LCD panel with other devices (such as control ICs or backlight modules).

Prior art cell tests include full contact test and shorting bar test. In a full contact test, each scan line and each data line is electrically connected to an individual test pad, and test signals are applied from a test probe. The full contact test provides accurate test results but requires long test time due to the difficulty in probe alignment. Also, since all scan lines and data lines are tested simultaneously, the test probe requires a large number of pins, which are difficult to manufacture and maintain. Also, LCD panels of different sizes can not share the same test equipment. On the other hand, in a shorting bar test, all scan lines or data lines are electrically connected to a test pad via a shorting bar. Therefore, the number of pins in the test probe can be largely reduced.

Reference is made to FIG. 1 for a diagram illustrating a prior art LCD device 100. The LCD device 100 includes a display area 105 and a non-display area. A plurality of parallel data lines D₁-Dₘ, a plurality of parallel gate lines G₁-Gₙ, and a plurality of display units P₁₁-Pₘₙ are disposed in the display area 105 of the LCD device 100. The data lines D₁-Dₘ and the gate lines G₁-Gₙ intersect each other and form a matrix in which the display units P₁₁-Pₘₙ are respectively disposed at corresponding intersections. Each display unit includes a thin film transistor (TFT) switch and a liquid crystal capacitor. Each liquid crystal capacitor is coupled to a corresponding data line via a corresponding TFT switch, while the control end of each TFT switch is coupled to a corresponding gate line.

A source driver 110, a gate driver 120 and test units 130, 140 are disposed in the non-display area of the LCD device 100. Based on the images to be displayed, the source driver 110 generates corresponding data signals, which are then transmitted to corresponding data lines D₁-Dₘ for charging the liquid crystal capacitors in corresponding display units P₁₁-Pₘₙ. The gate driver 120 can generate gate signals for turning on the TFT switches in corresponding display units P₁₁-Pₘₙ via corresponding gate lines G₁-Gₙ.

As depicted in FIG. 1, the test units 130 and 140 are disposed at the opposite sides of the terminal. In other words, the display area 105 of the LCD device 100 is disposed between the test unit 130 and the source driver 110, as well as between the test unit 140 and the gate driver 120. The test unit 130 includes shorting bars 132, 134, test pads DE, DO, DSWO, DSWE, and a plurality of switches. The test pads DO and DE are disposed at one end of the shorting bars 132 and 134, respectively. The test pad DSWO can receive switch control signals for turning on/off the switches coupled to the odd-numbered data lines, and the test pad DSWE can receive switch control signals for turning on/off the switches coupled to the even-numbered data lines. All odd-numbered data lines can be electrically connected to the shorting bar 132 and the test pad DO via corresponding switches, and all even-numbered data lines can be electrically connected to the shorting bar 134 and the test pad DE via corresponding switches. On the other hand, the test unit 140 includes shorting bars 142, 144, test pads GE, GO, GSW, and a plurality of switches. The test pads GO and GE are disposed at one end of the shorting bars 142 and 144, respectively. The test pad GSW can receive switch control signals for turning on/off the switches coupled to the gate lines. All odd-numbered gate lines can be electrically connected to the shorting bar 142 and the test pad GO via corresponding switches, and all even-numbered gate lines can be electrically connected to the shorting bar 144 and the test pad GE via corresponding switches.

In the prior art LCD device 100, cell tests can be performed by applying test signals to the test pads GO, GE, DO and DE from a test probe. Therefore, the number of pins in the test probe can be reduced and LCD devices of different sizes can share the same test equipment. However, the prior art LCD device 100 can only detect cell defects (such as the display units P₁₁-Pₘₙ) or line defects (such as the data lines D₁-Dₘ or the gate lines G₁-Gsₙ) in the display area, but is unable to detect layout defects in the non-display area.

### SUMMARY OF THE INVENTION

The present invention provides an LCD panel capable of detecting cell defects, line defects and layout defects, comprising a plurality of signal lines; a plurality of display units each coupled to a corresponding signal line among the plurality of signal lines; a driving circuit having a plurality of output ends each coupled to a corresponding signal line among the plurality of signal lines in order to provide driving signals for driving the display units; and a test unit comprising a shorting bar; a first test pad disposed at a first end of the shorting bar for receiving a test signal: and a plurality of switching devices each coupled between a corresponding output end among the plurality of output ends and the shorting bar for controlling signal transmission paths between the shorting bar and the plurality of signal lines based on the test signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a prior art LCD device.

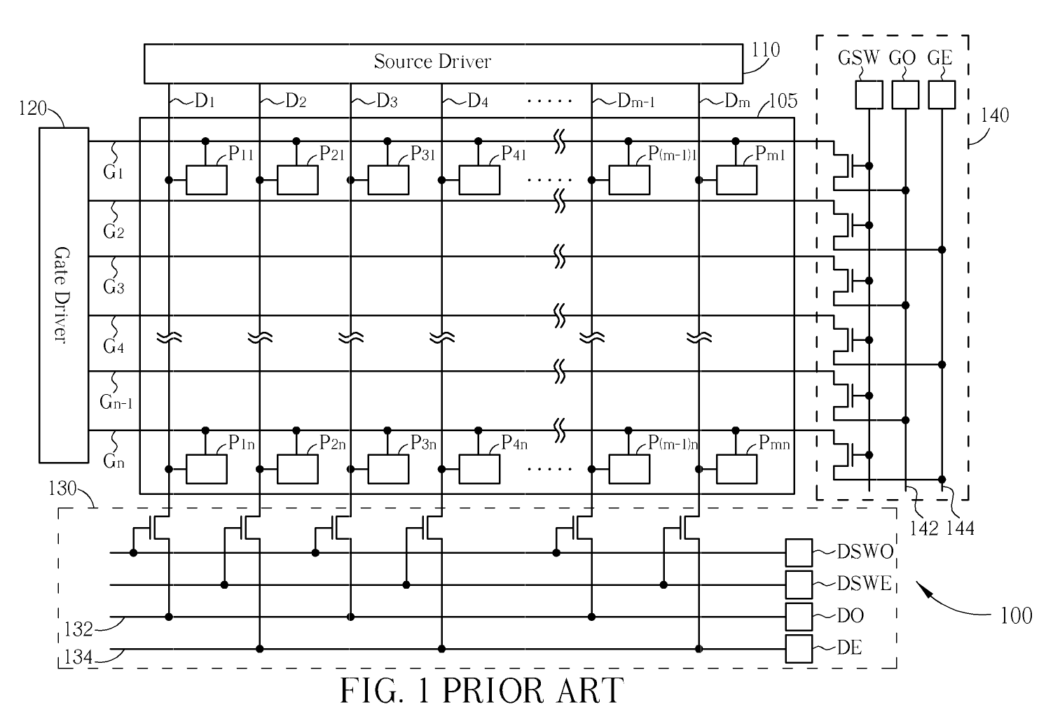

FIG. 2 is a diagram illustrating an LCD device according to a first embodiment of the present invention.

FIG. 3 is a diagram illustrating an LCD device according to a second embodiment of the present invention.

FIG. 4 is a diagram illustrating an LCD device according to a third embodiment of the present invention.

FIG. 5 is a diagram illustrating an LCD device according to a fourth embodiment of the present invention.

### DETAILED DESCRIPTION

Certain terms are used throughout the following description and claims to refer to particular components. As one skilled in the art will appreciate, manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . . ” The terms “couple” and “coupled” are intended to mean either an indirect or a direct electrical connection. Thus, if a first device couples to a second device, that connection may be through a direct electrical connection, or through an indirect electrical connection via other devices and connections.

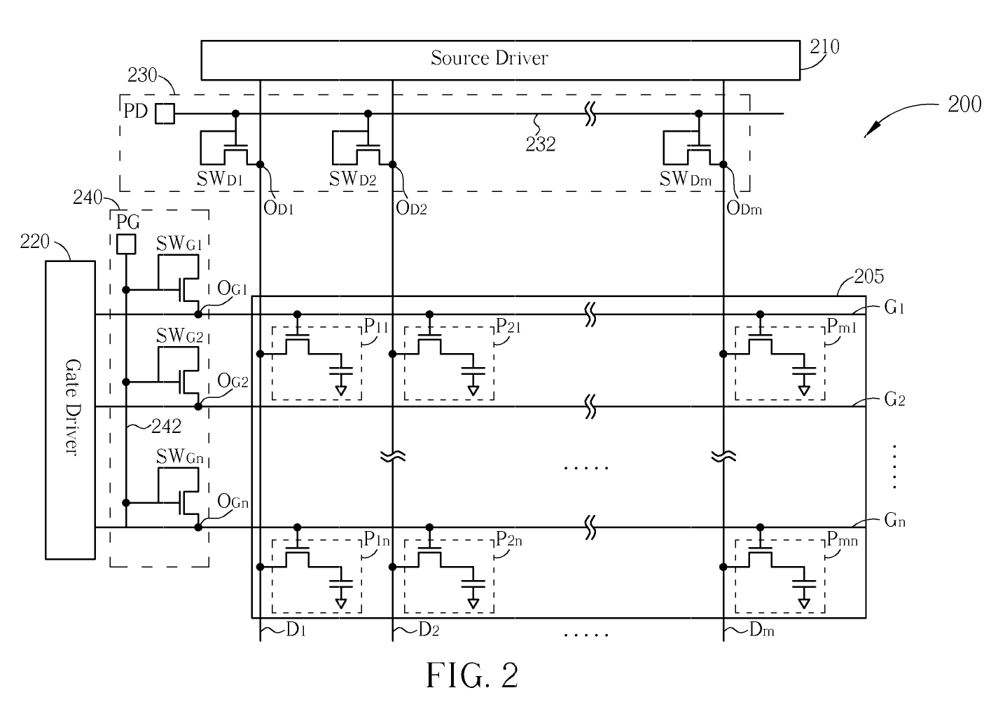

Reference is made to FIG. 2 for a diagram illustrating an LCD device 200 according to a first embodiment of the present invention. The LCD device 200 includes a display area 205 and a non-display area. A plurality of parallel data lines D₁-Dₘ, a plurality of parallel gate lines G₁-Gₙ, and a plurality of display units P₁₁-Pₘₙ are disposed in the display area 205 of the LCD device 200. The data lines D₁-Dₘ and the gate lines G₁-Gₙ intersect each other and form a matrix in which the display units P₁₁-Pₘₙ are respectively disposed at corresponding intersections. Each display unit includes a TFT switch and a liquid crystal capacitor. Each liquid crystal capacitor is coupled to a corresponding data line via a corresponding TFT switch, while the control end of each TFT switch is coupled to a corresponding gate line.

A source driver 210, a gate driver 220 and test units 230, 240 are disposed in the non-display area of the LCD device 200. Based on the images to be displayed, the source driver 210 generates corresponding data signals, which are then transmitted to corresponding data lines D₁-Dₘ respectively via the output ends O_{D1}-O_{Dm} of the source driver 210 for charging the liquid crystal capacitors in corresponding display units P₁₁-Pₘₙ. The gate driver 220 can generate gate signals, which are then transmitted to corresponding gate lines G₁-Gₙ respectively via the output ends O_{G1}-O_{Gn} of the gate driver 220 for turning on the TFT switches in corresponding display units P₁₁-Pₘₙ.

The test unit 230 includes a shorting bar 232, a test pad PD, and a plurality of switching devices SW_{D1}-SW_{Dm}. The output ends O_{D1}-O_{Dm} of the source driver 210 are coupled to the shorting bar 232 via corresponding switching devices SW_{D1}-SW_{Dm}, respectively. When performing panel tests, test signals can be inputted via the test pad PD for turning on (short-circuiting) the switching devices SW_{D1}-SW_{Dm} sequentially. Therefore, test signals can be transmitted to the data lines D₁-Dₘ via the output ends O_{D1}-O_{Dm} of the source driver 210, respectively. The test unit 240 includes a shorting bar 242, a test pad PG, and a plurality of switching devices SW_{G1}-SW_{Gn}. The output ends O_{G1}-O_{Gn} of the gate driver 220 are coupled to the shorting bar 242 via corresponding switching devices SW_{G1}-SW_{Gn}, respectively. When performing panel tests, test signals can be inputted via the test pad PG for turning on (short-circuiting) the switching devices SW_{G1}-SW_{Gn} sequentially. Therefore, test signals can be transmitted to the gate lines G₁-Gₙ via the output ends O_{G1}-O_{Gn} of the gate driver 220, respectively.

Thus, the LCD device 200 according to the first embodiment of the present invention can detect cell defects (such as the display units P₁₁-Pₘₙ) or line defects (such as the data lines D₁-Dₘ or the gate lines G₁-Gₙ) in the display area 205, as well as layout defects (such as the layout between the display area 205 and the output ends O_{D1}-O_{Dm} of the source driver 210, or the layout between the display area 205 and the output ends O_{G1}-O_{Gn} of the gate driver 220). Also, in the first embodiment of the present invention, the switching devices can include TFT switches as depicted in FIG. 2, or other devices having similar functions (such as diodes).

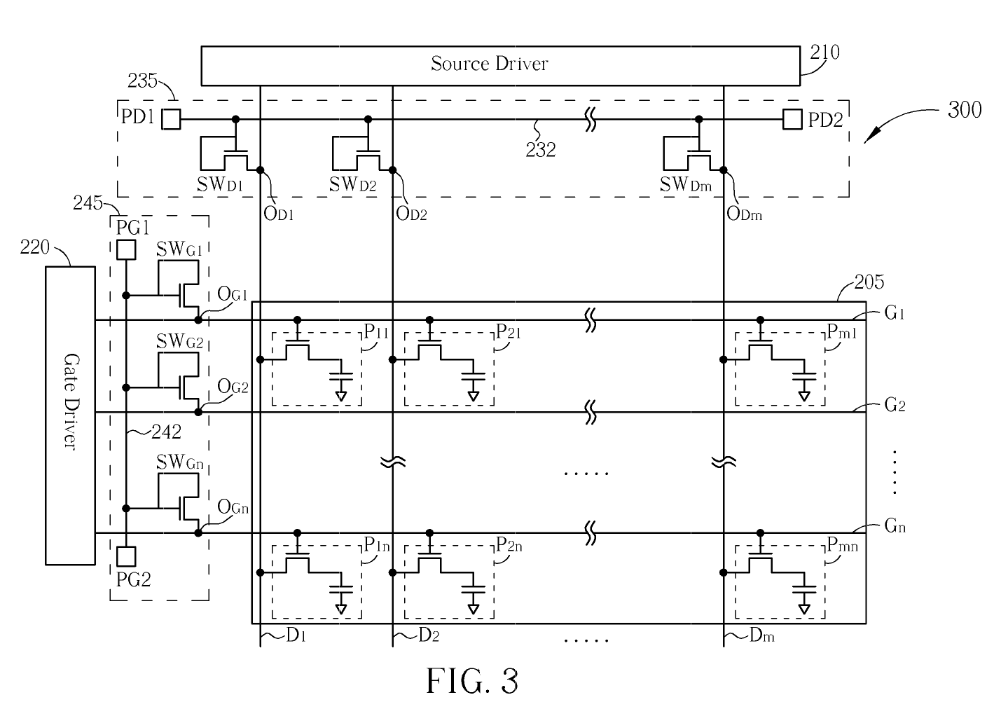

Reference is made to FIG. 3 for a diagram illustrating an LCD device 300 according to a second embodiment of the present invention. The LCD devices 200 and 300 have similar structures, but the non-display area of the LCD device 300 includes test units 235 and 245. Compared to the test units 230 and 240 of the first embodiment, the test units 235 and 245 each include two test pads PD1, PD2 and two test pads PG1, PG2. When performing panel tests, test signals can be inputted via the test pads PD1 and PD2 for turning on the switching devices SW_{D1}, SW_{D2}, SW_{D3}, . . . sequentially and turning on the switching devices SW_{Dm}, SW_{D(m-1)}, SW_{D(m-2)}, . . . sequentially. Therefore, test signals can be transmitted to the data lines D₁-Dₘ via the output ends O_{D1}-O_{Dm} of the source driver 210, respectively. Similarly, when performing panel tests, test signals can be inputted via the test pads PG1 and PG2 for turning on the switching devices SW_{G1}, SW_{G2}, SW_{G3}, . . . sequentially and turning on the switching devices SW_{Gn}, SW_{G(n-1)}, SW_{G(n-2)}, . . . sequentially. Therefore, test signals can be transmitted to the gate lines G₁-Gₙ via the output ends O_{G1}-O_{Gn} of the gate driver 220, respectively. Therefore, the LCD device 300 according to the third embodiment of the present invention can increase test speed.

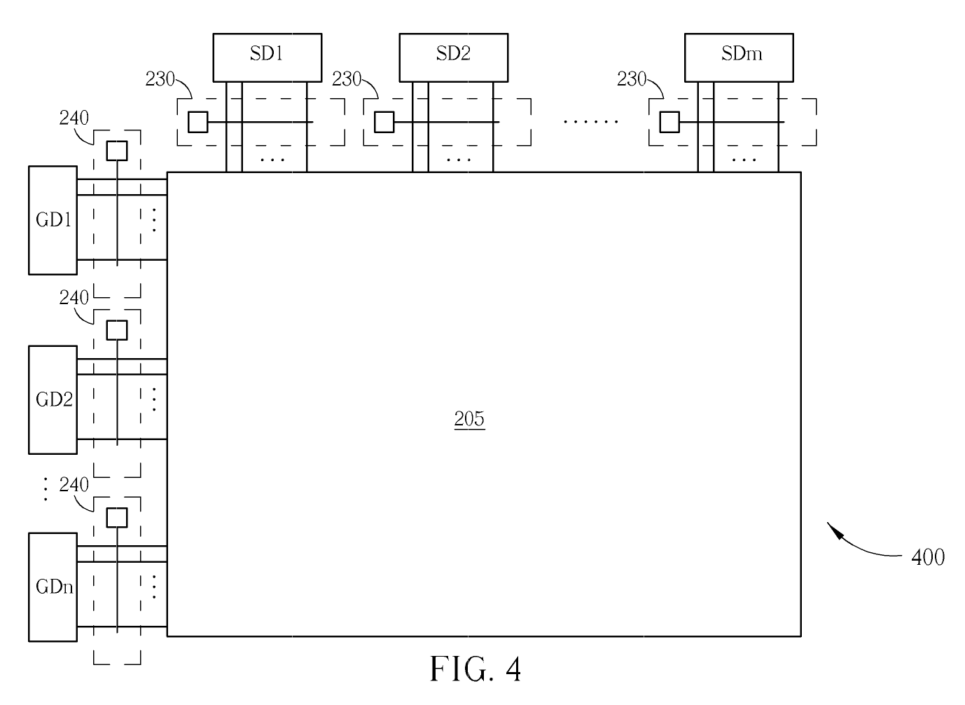

As the size of LCD panel is getting larger, the number of data lines and gate lines is also increased. Therefore, more source drivers or gate drivers are required for ensuring proper operations. Reference is made to FIG. 4 for a diagram illustrating an LCD device 400 according to a third embodiment of the present invention. The LCD devices 200 and 400 have similar structures, but the non-display area of the LCD device 400 includes a plurality of source drivers SD1-SDm, a plurality of gate drivers GD1-GDn, and a plurality of test units 230 and 240. The detail structures of the display 205 and each of the test units 230 and 240 are also illustrated in FIG. 2. Therefore, the LCD device 400 according to the third embodiment of the present invention can detect cell defects or line defects in the display area 205, as well as layout defects in the non-display area.

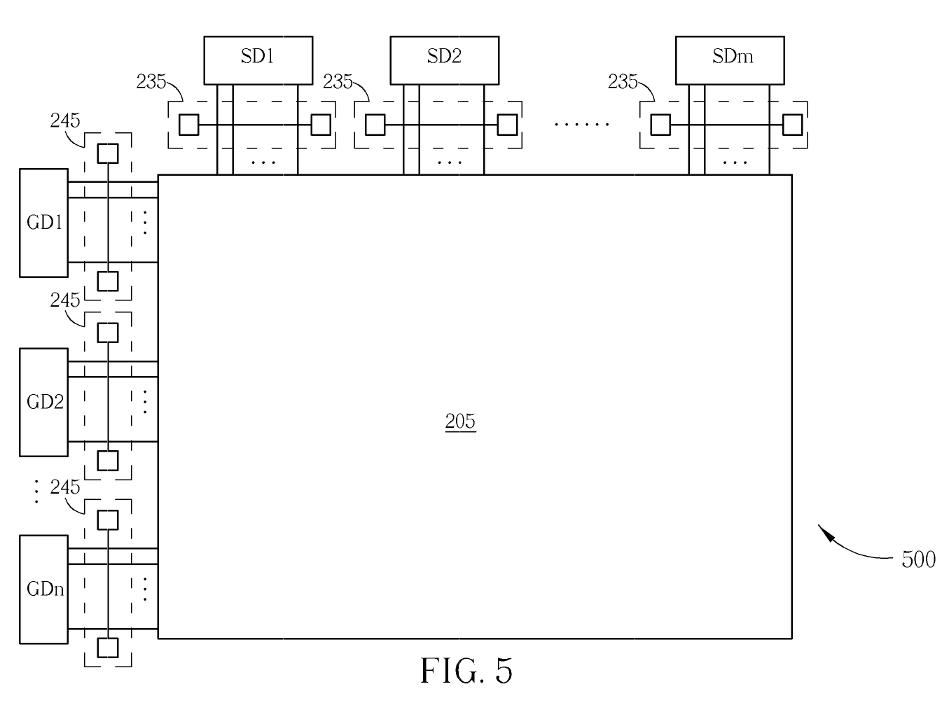

Reference is made to FIG. 5 for a diagram illustrating an LCD device 500 according to a fourth embodiment of the present invention. The LCD devices 300 and 500 have similar structures, but the non-display area of the LCD device 500 includes a plurality of source drivers SD1-SDm, a plurality of gate drivers GD1-GDn, and a plurality of test units 235 and 245. The detail structures of the display 205 and each of the test units 235 and 245 are also illustrated in FIG. 3. Therefore, the LCD device 500 according to the fourth embodiment of the present invention can detect cell defects or line defects in the display area 205, as well as layout defects in the non-display area.

Those skilled in the art will readily observe that numerous modifications and alterations of the device and method may be made while retaining the teachings of the invention.

What is claimed is:

1. A liquid crystal display (LCD) panel capable of detecting cell defects, line defects and layout defects, comprising:
a plurality of signal lines;
a plurality of display units each coupled to a corresponding signal line among the plurality of signal lines;
a driving circuit having a plurality of output ends each coupled to a corresponding signal line among the plurality of signal lines in order to provide driving signals for driving the display units; and
a test unit, comprising:
a shorting bar;
a first test pad disposed at a first end of the shorting bar for receiving a test signal: and
a plurality of switching devices each coupled between a corresponding output end among the plurality of output ends and the shorting bar for controlling signal transmission paths between the shorting bar and the plurality of signal lines based on the test signal.

2. The LCD panel of claim 1, further comprising:
a second test pad disposed at a second end of the shorting bar.

3. The LCD panel of claim 1, wherein each display unit includes a thin film transistor (TFT) switch and a liquid crystal capacitor.

4. The LCD panel of claim 1, wherein the plurality of signal lines include a data line for transmitting source signals corresponding to display images.

5. The LCD panel of claim 1, wherein the plurality of signal lines include a gate line for transmitting gate signals for turning on the display units.

6. The LCD panel of claim 1, wherein the driving circuit includes a source driver for providing the source signals corresponding to display images.

7. The LCD panel of claim 1, wherein the driving circuit includes a gate driver for transmitting gate signals required for turning on the display units.

8. The LCD panel of claim 1, wherein the switching devices include a TFT switch or a diode.
